(19) United States
(12) Patent Application Publication
(10) Pub. No.: US 2023/0314966 A1
(43) Pub. Date: Oct. 5, 2023

(54) MASK PROCESSING METHOD AND APPARATUS

(71) Applicant: TES Co., Ltd, Yongin-si (KR)

(72) Inventor: Hong-Jae LEE, Yongin-si (KR)

(73) Assignee: TES Co., Ltd, Yongin-si (KR)

(21) Appl. No.: 18/127,505

(22) Filed: Mar. 28, 2023

(30) Foreign Application Priority Data
Mar. 29, 2022 (KR) 10-2022-0039220

(51) Int. Cl. G03F 7/00; G03F 7/09; G03F 7/16; G03F 7/36; G03F 7/20; C23C 16/455

(52) U.S. Cl. CPC G03F 7/70991; G03F 7/09; G03F 7/167; G03F 7/36; G03F 7/2004; C23C 16/45565

(57) ABSTRACT

There are provided a mask processing method and a mask processing apparatus for reusing a mask used in an organic material deposition process. The mask processing method includes: (a) forming a sacrificial layer on a mask in a first chamber; (b) transferring the mask to a second chamber in which a substrate is disposed, and then processing the substrate using the mask; and (c) removing the sacrificial layer on the mask.

### CROSS-REFERENCE TO RELATED APPLICATION

This application claims priority to Korean Patent Application No. 10-2022-0039220 (filed on Mar. 29, 2022), which is incorporated herein by reference in its entirety.

### BACKGROUND

The present invention relates to a mask processing method for reusing a mask used in an OLED deposition process or the like.

Further, the present invention relates to a mask processing apparatus capable of processing a mask.

An OLED display manufacturing process involves the deposition of light emitters. Since organic materials are used as light emitters in OLED displays, the deposition of organic materials is required in the OLED display manufacturing process. Also, in the OLED display manufacturing process, a mask such as a fine metal mask (FMM) is used to maintain the shape of an organic material to be deposited.

In order to minimize thermal expansion in an FMM mask, an INVAR material having a small coefficient of thermal expansion is usually used. Also, FMM masks that are used over a large area have been used by a reinforcing stick to prevent sagging in the center.

After an FMM on which an organic material is deposited is introduced into a bath filled with a solvent such as N-methyl-2-pyrrolidone (NMP) for reuse, the organic material deposited on the FMM is removed by a wet cleaning method. However, in the case of the wet cleaning method, some of the organic solvent may remain on the mask after cleaning is completed. In addition, organic solvents such as NMP used in the wet cleaning method have a disadvantage in that a large amount of wastewater is generated, and as a hazardous material, the use thereof may be limited from the environmental point of view.

Korean Patent No. 10-1367218 (Feb. 26, 2014) discloses an apparatus and method for cleaning an OLED deposition mask. Specifically, the above document suggests that a mask on which an organic compound and an inorganic compound are deposited is primarily dry-cleaned and then wet-cleaned. However, in the case of this method, cleaning efficiency is low in that dry cleaning and wet cleaning cannot be performed in one chamber.

### SUMMARY

One problem to be solved by the present invention is to provide a mask processing method, which is capable of effectively removing impurities on a mask in order to reuse a mask used in an organic deposition process.

Another problem to be solved by the present invention is to provide a mask processing apparatus, which is capable of depositing a sacrificial layer on a mask and removing the sacrificial layer.

A mask processing method according to the present invention for solving the above problems is characterized by including: (a) forming a sacrificial layer on a mask in a first chamber; (b) transferring the mask to a second chamber in which a substrate is disposed, and then processing the substrate using the mask; and (c) removing the sacrificial layer on the mask.

Step (c) is preferably performed in the first chamber.

The sacrificial layer may include a compound containing silicon. Step (a) may be performed by an atomic layer deposition (ALD) or chemical vapor deposition (CVD) method using a silicon containing precursor and a reaction gas. The reaction gas may be plasmatized outside the first chamber and supplied into the first chamber. Step (a) may include (a1) supplying a silicon containing precursor gas as a reaction gas into the first chamber, (a2) purging the first chamber by supplying a purge gas into the first chamber, (a3) supplying O₂ radicals as a reaction gas into the first chamber, and (a4) purging the first chamber by supplying a purge gas into the first chamber.

Step (b) may include an organic material deposition step. In this case, it is preferred that Step (c) further includes removing at least a portion of organic impurities on the surface of the mask by plasmatized oxygen gas to the mask.

Step (c) is preferably performed by a dry cleaning method.

Step (c) may include (c1) forming a salt from a cleaning gas, (c2) forming reaction by-products by reacting the formed salt with the sacrificial layer, and (c3) removing the reaction by-products.

Step (c3) may be performed by a method of decomposing or evaporating reaction by-products through heating.

In Step (a), the sacrificial layer is formed of silicon oxide, and in Step (c), the cleaning gas includes hydrogen fluoride gas and ammonia gas, and reactions according to the following 1) to 3) may be performed:

HF+NH₃→NH₄F 1)

6NH₄F+SiO₂→(NH₄)₂SiF₆+2H₂O+4NH₃ 2)

(NH₄)₂SiF₆→2NH₃+SiF₄+2HF. 3)

A mask processing method according to the present invention for solving the above problems is characterized by including: (a) forming a silicon oxide layer on the mask by supplying a silicon-containing gas and an oxygen-containing gas into a first chamber; (b) transferring the mask to a second chamber in which a substrate is disposed; (c) depositing an organic material on the substrate using the mask in the second chamber; (d) transferring the mask that organic material is deposited to the first chamber; (e) removing at least a portion of organic impurities deposited on the surface of the mask in Step (c) by providing an oxygen-containing gas to the mask in the first chamber; and (f) removing the silicon oxide layer on the mask by a dry cleaning method using a cleaning gas in the first chamber.

The oxygen-containing gas in Step (a) and the oxygen-containing gas in Step (e) may be plasmatized outside the first chamber and supplied into the first chamber.

Step (f) may include (f1) forming a salt from a cleaning gas including a fluorine-containing gas and a hydrogen-containing gas, (f2) forming reaction by-products by reacting the formed salt with the silicon oxide layer, and (f3) decomposing or evaporating the reaction by-products through heating.

A mask processing apparatus according to the present invention for solving the above problems is characterized by including a chamber; a susceptor provided inside the chamber and supporting a mask to be processed on the lower surface; a shower head provided in a lower region inside the chamber so as to face the susceptor and spraying gas toward the mask; a gas supply unit that selectively supplies a sacrificial layer deposition gas, an organic impurity removal gas, and a sacrificial layer removal gas into the shower head; and a gas exhaust unit for exhausting the gas inside the chamber.

A lamp disposed on the inner side of the chamber may additionally be included.

The gas supply unit may be connected to an oxygen gas reservoir, a precursor gas reservoir and a cleaning gas reservoir.

A remote plasma generator located outside the chamber and plasmatizing at least a portion of gas supplied into the chamber may additionally be included. The remote plasma generator may be disposed in the gas supply unit.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a flowchart schematically illustrating a mask processing method according to the present invention;

FIG. 2A schematically illustrates a mask processing method according to an exemplary embodiment of the present invention, focusing on a mask;

FIG. 2B schematically illustrates a mask processing method according to another exemplary embodiment of the present invention, focusing on a mask; and

FIG. 3 schematically illustrates a mask processing apparatus according to an exemplary embodiment of the present invention.

### DETAILED DESCRIPTION

The benefits and features of the present application, and the methods of achieving the benefits and features will become apparent with reference to embodiments to be described below in detail along with the accompanying drawings. However, the present invention is not limited to the embodiments to be disclosed below, may be implemented in various other forms, and the embodiments are only provided for rendering the disclosure of the present invention complete and for fully representing the scope of the invention to a person with ordinary skill in the technical field to which the present invention pertains, and the present invention will be defined only by the scope of the claims. Throughout the specification, like reference numerals indicate like constituent elements. The sizes and relative sizes of the layers and regions in the drawing may be exaggerated for clarity of description.

When a device or layer is referred to as another device or “on” or “above” another device or layer, it includes not only the case where another device or layer is directly on another device or layer, but also the case where another layer or another device is interposed therebetween. In contrast, when a device is referred to as “directly on” or “directly above,” it indicates that no other device or layer is interposed therebetween. In addition, when one constituent element is described as being “connected,” “coupled” or “linked” to another constituent element, the constituent elements may be directly connected or linked, but it should be understood that another constituent element may be “interposed” between each constituent element, or each constituent element may also be “connected,” “coupled” or “linked” through another constituent element.

Spatially relative terms, such as “below,” “lower,” “above,” and “upper” may be used to easily describe one device or a device different from constituent elements or a relationship between constituent elements as illustrated in the figures. The spatially relative terms should be understood as terms including different directions of a device in use or operation in addition to the directions illustrated in the drawings. For example, when the device illustrated in the figures is turned over, the device described as disposed “below” another device may be disposed “above” the other device. Accordingly, the exemplary term “below” may include orientations of both below and above. Furthermore, in the present invention, “stacking” may refer to not only stacking in the vertical direction but also stacking in the horizontal direction.

The terms used in the present specification are used merely to describe embodiments, and thus are not intended to limit the present invention. In the present specification, the singular forms include the plural forms unless otherwise specified in the phrases. As used herein, “include” and/or “including” means that the mentioned constituent elements, steps, operations and/or devices are present and does not exclude the presence or addition of one or more other constituent elements, steps, operations and/or devices.

Hereinafter, a mask processing apparatus and method according to preferred embodiments of the present invention will be described in detail with reference to the accompanying drawings.

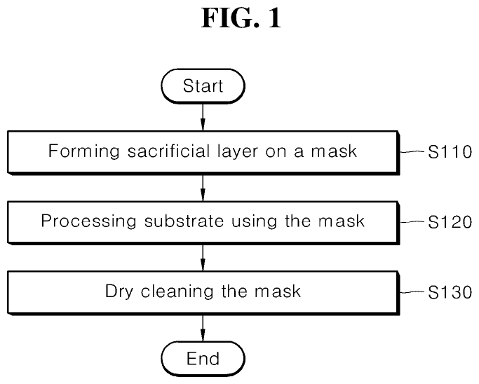

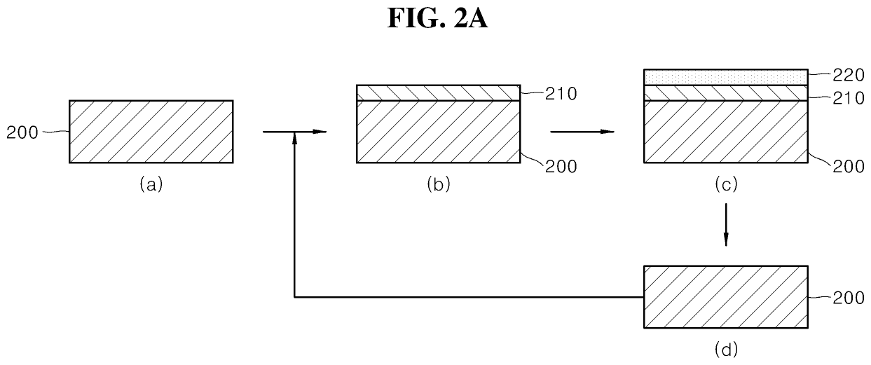

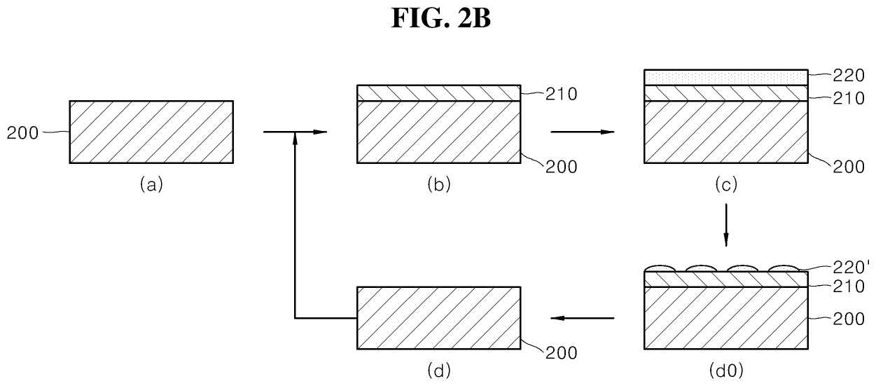

FIG. 1 is a flowchart schematically illustrating a mask processing method according to the present invention. FIG. 2A schematically illustrates a mask processing method according to an exemplary embodiment of the present invention, focusing on a mask, and in describing the mask processing method according to FIG. 1, reference is made to FIG. 2A.

Referring to FIGS. 1 and 2A, the mask processing method according to the present invention includes forming a sacrificial layer on a mask (S110), processing a substrate using the mask (S120), and cleaning the mask (S130).

In the forming of the sacrificial layer on the mask (S110), a sacrificial layer 210 is formed on a mask 200 in a first chamber ((b) of FIG. 2A).

In the present invention, impurities 220 such as organic materials and reaction by-products deposited or attached to the surface of the sacrificial layer are removed together by removing the sacrificial layer 210. That is, in the present invention, the sacrificial layer 210 refers to a layer capable of removing the impurities 220 present thereon by removing the sacrificial layer 210.

The sacrificial layer 210 may be formed of, for example, a silicon-containing compound such as silicon oxide or silicon nitride. Such silicon-containing compounds may be formed by a method such as atomic layer deposition (ALD) and chemical vapor deposition (CVD), and from the viewpoint of forming a sacrificial layer as thin as possible and from the viewpoint of depositing a sacrificial layer with high step coverage for a fine mask pattern, the sacrificial layer may be preferably formed by the ALD method.

In an exemplary embodiment of forming a sacrificial layer by the ALD method, a precursor gas may be supplied as a source gas, and O₂ radicals generated by a remote plasma generator may be supplied as a reaction gas.

In order to improve reaction efficiency, a reaction gas such as oxygen gas may be plasmatized outside a first chamber through a remote plasma generator and supplied into the first chamber. When the sacrificial layer is formed by the ALD method, the silicon containing precursor gas may be supplied into the first chamber without passing through the remote plasma generator. Alternatively, when the sacrificial layer is formed by the CVD method, the silicon containing precursor gas may be plasmatized through a remote plasma generator and supplied into the first chamber.

The forming of the sacrificial layer (S110) may include (a1) adsorbing a silicon containing precursor on the surface of a mask by supplying the silicon containing precursor as a reaction gas into the first chamber, (a2) a first purge step of purging the first chamber by supplying a purge gas into the first chamber, (a3) forming silicon oxide by supplying O₂ radicals as a reaction gas into the first chamber, and (a4) a second purge step of purging the first chamber by supplying a purge gas into the first chamber. A cycle including the absorption step, the first purge step, the reaction step and the second purge step may be performed one or more times.

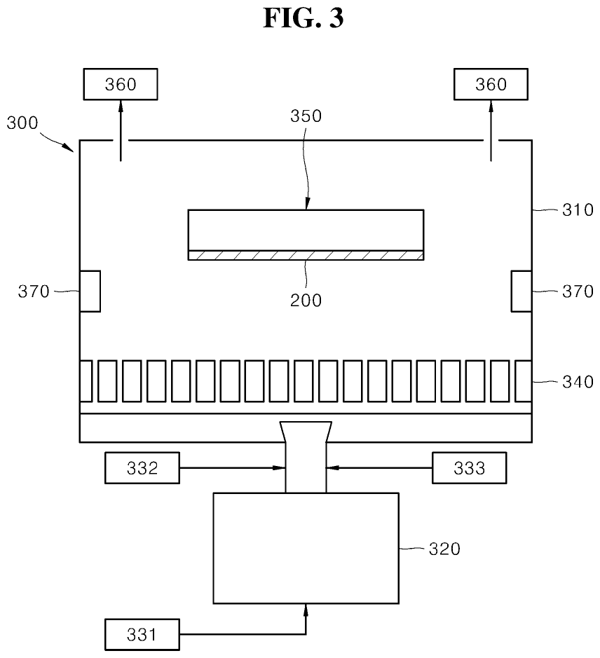

The sacrificial layer 210 may be formed in a first chamber as in the example illustrated in FIG. 3. The first chamber is a mask processing chamber, and may be included in a cluster along with a deposition chamber, a load lock chamber, and the like. For example, the first chamber may be a mask processing chamber included in an OLED deposition cluster. As a result, while a deposition process for a substrate is performed using a specific mask in a deposition chamber (second chamber), a process of depositing a sacrificial layer for other masks or a cleaning process to be described below may be performed in the mask processing chamber (first chamber). In this case, the mask can be processed while maintaining the vacuum state.

Next, in the processing of the substrate using the mask (S120), the mask 200 is transferred to a second chamber in which a substrate is disposed, and is disposed on the substrate, and then the substrate is processed using the mask 200. The second chamber may be a deposition chamber, and in this case, the processing of the substrate may include depositing an organic material or inorganic material on the substrate in a state in which the mask 200 is disposed on the entire surface of the substrate.

In particular, the processing of the substrate may include depositing an organic material on the substrate in a state in which the mask is disposed on the entire surface of the substrate. A mask used for the deposition of an organic material may be a fine metal mask (FMM), an open metal mask (OMM), or the like. For example, a plurality of holes is formed in an FMM. In the FMM, an INVAR alloy material is usually used to minimize thermal expansion, and in the case of a large area, the FMM is used while a reinforcing stick is used to prevent sagging in the center. The vapor of an organic material to be deposited passes through the holes of the FMM to be deposited on the positions on the substrate corresponding to the holes.

In this case, not all the organic vapor passes through the FMM, and the organic vapor cannot pass through the FMM between the holes of the FMM and is deposited on the surface of the FMM ((c) of FIG. 2A). Further, reaction by-products may also be deposited on the FMM surface. When the thickness of impurities 220 such as organic materials or reaction by-products deposited on the FMM surface increases, problems such as deposition inaccuracy and contamination may occur, so these impurities 220 need to be removed. A mask cleaning step as described below is performed to remove such impurities.

Meanwhile, the mask processing method according to an exemplary embodiment of the present invention may include a heating step for decomposing or evaporating reaction by-products generated on the mask. Since the mask is exposed to a high temperature in the heating step, it may be preferable to use a mask made of an INVAR (a Fe alloy containing about 36.5 wt % of Ni) material having a low coefficient of thermal expansion, and in addition, a mask made of a material having a coefficient of thermal expansion similar to that of INVAR may be used.

Next, in the mask cleaning step (S130), the sacrificial layer on the mask is removed ((d) of FIG. 2A).

For the cleaning of the mask 200, as is widely known, a method of directly removing impurities by wet cleaning and/or dry cleaning is used. However, the wet cleaning method may have problems such as environmental problems and residual solvent on the surface of the mask, and the dry cleaning method may have problems in which impurities, particularly, organic impurities, are not completely removed.

In this case, in the present invention, the removal of impurities through the sacrificial layer 210 is employed as a main mask cleaning method instead of directly removing the impurities 220. In addition, by forming the sacrificial layer 210 with a silicon-containing compound such as silicon oxide or silicon nitride, the sacrificial layer 210 can be easily removed by a dry cleaning method, and as a result, impurities can be easily removed along with the sacrificial layer 210 even though the impurities 220 deposited or attached on the sacrificial layer 210 are not directly removed.

The sacrificial layer 210 may be removed by a wet cleaning method or a dry cleaning method. Among them, since the removal of the sacrificial layer through wet cleaning generates a large amount of wastewater and requires the use of organic solvents, which are hazardous materials, the removal of the sacrificial layer through dry cleaning is more preferred.

An example of removing the sacrificial layer through dry cleaning is as follows.

i. A cleaning gas is supplied into a first chamber in which a mask to be cleaned is disposed, and a salt is formed from the supplied cleaning gas. The salt is a salt capable of chemically reacting with the sacrificial layer. For example, when the sacrificial layer is a silicon oxide material, the salt may be ammonium fluoride (NH₄F). Ammonium fluoride may be produced through a chemical reaction between hydrogen fluoride (HF) gas and ammonia (NH₃) gas. In this case, hydrogen fluoride gas and ammonia gas may constitute a cleaning gas. An inert gas such as argon gas may be supplied into the first chamber together with the cleaning gas to improve uniformity.

ii. Reaction by-products are formed by reacting the formed salt with the sacrificial layer. For example, ammonium fluoride may react with silicon oxide to form reaction by-products such as (NH₄)₂SiF₆.

iii. Next, a step of removing the reaction by-products may be included. The reaction by-products may be removed by a method of increasing the surface temperature of the mask to about 120 to 150° C. through heating to decompose or evaporate the reaction by-products. In summary, when the sacrificial layer is formed of silicon oxide and the cleaning gas includes hydrogen fluoride gas and ammonia gas, the reaction for removing the sacrificial layer as described above may consist of the reactions according to the following 1) to 3):

HF+NH₃→NH₄F 1)

6NH₄F+SiO₂→(NH₄)₂SiF₆+2H₂O+4NH₃ 2)

(NH₄)₂SiF₆→2NH₃+SiF₄+2HF. 3)

Meanwhile, the mask may be cleaned in the first chamber or a separate chamber. Preferably, the mask is cleaned in the first chamber. When the mask is cleaned in a third chamber, a separate chamber may be required, thereby increasing equipment/process costs.

Although the above description has been made by assuming that the sacrificial layer is formed of silicon oxide, the sacrificial layer may be formed of other types of silicon-containing compounds, such as silicon nitride, and a sacrificial layer formed of other types of silicon-containing compounds may also be removed by selecting etching gases that form salts capable of reacting with the silicon-containing compounds.

FIG. 2B schematically illustrates a mask processing method according to another exemplary embodiment of the present invention, focusing on a mask. Although FIG. 2B has much in common with FIG. 2A, a process of removing organic impurities is additionally included.

When the substrate processing step (S120) includes the deposition of an organic material, the mask cleaning step may further include removing at least a portion of the organic impurities on the surface of the mask before removing the sacrificial layer ((d0) of FIG. 2B).

Organic impurities 220 may be removed by plasmatizing an oxygen-containing gas and providing the plasmatized gas to the mask. The oxygen-containing gas for removing organic impurities 220 may be oxygen gas, ozone gas, or the like. For example, when oxygen radicals in oxygen gas, which has been plasmatized, react with carbon and hydrogen of organic materials, CO, CO₂, H₂O, and the like are produced, and organic impurities 220 on the surface of the mask 200 may be removed to some extent. When the organic impurities are removed to some extent using oxygen radicals, the exposed area of the sacrificial layer 210 below organic impurities 220′ is relatively increased, and the efficiency of removing the sacrificial layer 210 by dry cleaning, and the like may be significantly increased.

A preferred example of the mask processing method in the organic material deposition process according to the present invention is as follows.

First, a silicon-containing gas and an oxygen-containing gas are supplied into a first chamber (chamber for processing a mask) to form a silicon oxide layer on the mask by the ALD method or the CVD method. The silicon oxide layer acts as a sacrificial layer for removing organic impurities on the surface of the mask. To increase reaction efficiency, the oxygen-containing gas may be plasmatized in a remote plasma generator outside a first chamber and supplied into the first chamber. Further, it is preferable to form a silicon oxide layer by the ALD method in order to control the thickness of the sacrificial layer as accurately as possible. A silicon oxide layer may be formed at room temperature through the combination of the remote plasma generation method and the ALD method.

Next, the mask is transferred to a second chamber (chamber for depositing organic materials) in which a substrate is disposed, and the mask is disposed on the substrate.

Next, an organic material is deposited on the substrate using the mask in the second chamber. In this case, organic impurities are deposited on the surface of the mask. After the organic deposition process is completed in the second chamber, the mask is transferred to the first chamber for cleaning the mask.

Next, at least a portion of the organic impurities deposited on the surface of the mask are removed by providing an oxygen-containing gas to the mask in the first chamber. The oxygen-containing gas supplied into the first chamber to remove organic impurities may be oxygen gas, ozone gas, or the like. In addition, in order to increase reaction efficiency, oxygen gas may be plasmatized outside the first chamber by a remote plasma generator and supplied into the first chamber. As described above, when the organic impurities are removed to some extent using plasmatized oxygen gas, the exposed area of the sacrificial layer below the organic impurities, that is, the silicon oxide layer, is relatively increased, and the efficiency of removing the silicon oxide layer by dry cleaning may be significantly increased.

Thereafter, the silicon oxide layer on the mask is removed by a dry cleaning method using a cleaning gas in the first chamber to also remove organic impurities remaining thereon.

Dry cleaning for removing the silicon oxide layer on the surface of the mask may include a salt formation step, a salt reaction step and a heating step. In the salt formation step, a salt is formed from a cleaning gas including a fluorine-containing gas (for example, hydrogen fluoride gas, nitrogen trifluoride gas, and the like) and a hydrogen-containing gas (for example, ammonia gas, hydrogen gas, and the like). The fluorine-containing gas and the hydrogen-containing gas may be provided at a flow rate ratio of 0.5:1 to 1:0.5, more preferably 0.8:1 to 1:0.8, and most preferably 1:1, but are not limited thereto. The cleaning gas may be supplied into the first chamber in a non-plasma state or in a plasma state. The cleaning gas may be supplied into the first chamber along with an inert gas such as argon gas. The inert gas may be supplied at a flow rate about 2 to 8-fold that of the fluorine-containing gas. In the salt reaction step, the formed salt reacts with the silicon oxide layer to form reaction by-products. During the salt reaction, the temperature of a susceptor may be controlled to about 30 to 40° C., and the temperature of the inner wall of the first chamber may be controlled to about 60 to 90° C., but they are not limited thereto. In the heating step, for example, the reaction by-products are decomposed or evaporated by heating the surface of the mask to about 120 to 150° C. using a lamp.

In this embodiment, the gases supplied in the silicon oxide deposition step and the organic impurity removal step may be plasmatized in the first chamber, or more preferably, may be plasmatized outside the first chamber by a remote plasma generator and then supplied into the first chamber. Through this, the efficiency of depositing silicon oxide and removing organic impurities may be increased.

FIG. 3 schematically illustrates a mask processing apparatus according to an exemplary embodiment of the present invention.

Referring to FIG. 3, a mask processing apparatus 300 according to the present invention includes a chamber 310, a gas supply unit 320, a shower head 340, a susceptor 350 and a gas exhaust unit 360. In addition, the mask processing apparatus according to the present invention may further include a lamp 370.

The gas supply unit 320 is a unit that supplies gases required for various reactions (sacrificial layer production reaction, organic material removal reaction, sacrificial layer removal reaction, and the like). The gas supply unit 320 is disposed so as to partially pass through a part of the bottom of the chamber 310. The gas supply unit is connected to a plurality of gas reservoirs 331, 332, and 333. For example, as in the example illustrated in FIG. 3, the gas supply unit 320 may be connected to each of an oxygen gas reservoir 331, a precursor gas reservoir 332, and a cleaning gas reservoir 333. Here, a precursor gas used for depositing a sacrificial layer is stored in the precursor gas reservoir 332, and for example, diisopropylaminosilane (DIPAS) may be used as the precursor gas, but the precursor gas is not limited thereto.

Furthermore, when a sacrificial layer is deposited by the ALD method in the mask processing apparatus, it is possible to perform a cycle of first supplying a precursor gas stored in the precursor gas reservoir 332 as a reaction gas, and then supplying a purge gas through the cleaning gas reservoir 333 or a separate gas reservoir (not shown), and then supplying O₂ radicals as a reaction gas through the gas supply unit 320, and again supplying a purge gas through the gas reservoir 333 or a separate gas reservoir (not shown) one or more times.

The shower head 340 for distributing gases is disposed in a relatively lower region inside the chamber 310 and is also disposed on the gas supply unit 320.

The susceptor 350 is disposed in a relatively upper region inside the chamber 310 so as to face the shower head 340, and a mask to be processed is disposed on the lower surface. The present invention is characterized in that the mask is fixed below the susceptor 350, which corresponds to the case that the substrate is fixed under the susceptor and the mask is disposed below the substrate in the organic material deposition chamber. Through such a configuration, more efficient mask transfer and disposition may be brought about in a state in which a vacuum state is maintained in an organic material deposition cluster.

The gas exhaust unit 360 is disposed so as to partially pass through the top or side of the chamber 310. A vacuum pump may be included or coupled to the gas exhaust unit 360.

The lamp 370 may be disposed on the inner side of the chamber 310. The lamp 370 may be disposed at a position where the surface of the mask 200 can be heated. For example, the lamp 370 may be disposed at a height similar to that at which the mask 200 is disposed.

Meanwhile, the mask processing apparatus according to the present invention may further include a remote plasma generator. The remote plasma generator is located outside the chamber and plasmatizes at least a portion of the gas supplied into the chamber. The remote plasma generator may be disposed in the gas supply unit 320 or integrated with the gas supply unit 320.

As described above, according to the mask processing method according to the present invention, an organic material deposition process, and the like are performed in a state in which a sacrificial layer is formed on the surface of a mask, and then organic impurities and the like on the mask can be removed by removing the sacrificial layer by the dry cleaning method.

According to the mask processing method according to the present invention, an organic material deposition process is performed in a state in which a sacrificial layer is formed on the surface of a mask, and impurities such as organic materials on the mask can be removed by removing the sacrificial layer. Since such a sacrificial layer can also be removed by a dry cleaning method, the impurities on the mask can be effectively removed by the mask processing method according to the present invention.

Further, when the mask processing apparatus according to the present invention is used, a sacrificial layer can be deposited on the mask, and the sacrificial layer can also be removed. In addition, the mask processing apparatus according to the present invention can use remote plasma, and thus, can enhance the efficiencies of depositing and removing the sacrificial layer.

The effects of the present invention are not limited to the above-mentioned effects, and other objects that are not mentioned may be clearly understood by those skilled in the art from the following detailed description.

Although the embodiments of the present invention have been mainly described above, various changes and modifications can be made at the level of those skilled in the art. Such changes and modifications may belong to the present invention without departing from the scope of the present invention. Therefore, the scope of the present invention should be determined by the claims described below.

What is claimed is:

1. A mask processing method, the method comprising:
(a) forming a sacrificial layer on a mask in a first chamber;
(b) transferring the mask to a second chamber in which a substrate is disposed, and then processing the substrate using the mask; and
(c) removing the sacrificial layer on the mask.

2. The mask processing method of claim 1, wherein Step (c) is performed in the first chamber.

3. The mask processing method of claim 1, wherein the sacrificial layer comprises a compound containing silicon.

4. The mask processing method of claim 1, wherein Step (a) is performed by an ALD or CVD method using a silicon containing precursor and a reaction gas.

5. The mask processing method of claim 4, wherein the reaction gas is plasmatized outside the first chamber and supplied into the first chamber.

6. The mask processing method of claim 4, wherein Step (a) comprises
(a1) supplying a silicon containing precursor gas as a reaction gas into the first chamber,
(a2) purging the first chamber by supplying a purge gas into the first chamber,
(a3) supplying O₂ radicals as a reaction gas into the first chamber, and
(a4) purging the first chamber by supplying a purge gas into the first chamber.

7. The mask processing method of claim 1, wherein Step (b) comprises an organic material deposition step.

8. The mask processing method of claim 7, wherein Step (c) further comprises removing at least a portion of organic impurities on the surface of the mask by plasmatized oxygen gas to the mask.

9. The mask processing method of claim 1, wherein Step (c) is performed by a dry cleaning method.

10. The mask processing method of claim 9, wherein Step (c) comprises
(c1) forming a salt from a cleaning gas,
(c2) forming reaction by-products by reacting the formed salt with the sacrificial layer, and
(c3) removing the reaction by-products of reaction.

11. The mask processing method of claim 10, wherein Step (c3) is performed by a method of decomposing or evaporating reaction by-products through heating.

12. The mask processing method of claim 10, wherein in Step (a), the sacrificial layer is formed of silicon oxide,
the cleaning gas comprises hydrogen fluoride gas and ammonia gas, and
in Step (c), reactions according to the following 1) to 3) are performed.
HF+NH₃→NH₄F 1)
6NH₄F+SiO₂→(NH₄)₂SiF₆+2H₂O+4NH₃ 2)
(NH₄)₂SiF₆→2NH₃+SiF₄+2HF. 3)

13. A mask processing method, the method comprising:
(a) forming a silicon oxide layer on the mask by supplying a silicon-containing gas and an oxygen-containing gas into a first chamber;
(b) transferring the mask to a second chamber in which a substrate is disposed;
(c) depositing an organic material on the substrate using the mask in the second chamber;
(d) transferring the mask that organic material is deposited to the first chamber;
(e) removing at least a portion of organic impurities deposited on the surface of the mask in Step (c) by providing an oxygen-containing gas to the mask in the first chamber; and
(f) removing the silicon oxide layer on the mask by a dry cleaning method using a cleaning gas in the first chamber.

14. The mask processing method of claim 13, wherein the oxygen-containing gas in Step (a) and the oxygen-containing gas in Step (e) are plasmatized outside the first chamber and supplied into the first chamber.

15. The mask processing mask processing method of claim 13, wherein Step (f) comprises
(f1) forming a salt from a cleaning gas comprising a fluorine-containing gas and a hydrogen-containing gas,
(f2) forming reaction by-products by reacting the formed salt with the silicon oxide layer, and
(f3) decomposing or evaporating the reaction by-products through heating.

16. A mask processing apparatus, the apparatus comprising:
a chamber;
a susceptor provided inside the chamber and supporting a mask to be processed on the lower surface;
a shower head provided in a lower region inside the chamber so as to face the susceptor and spraying gas toward the mask;
a gas supply unit that selectively supplies a sacrificial layer deposition gas, an organic impurity removal gas, and a sacrificial layer removal gas into the shower head; and
a gas exhaust unit for exhausting the gas inside the chamber.

17. The mask processing apparatus of claim 16, further comprising a lamp disposed on the inner side of the chamber.

18. The mask processing apparatus of claim 16, wherein the gas supply unit is connected to an oxygen gas reservoir, a precursor gas reservoir and a cleaning gas reservoir.

19. The mask processing apparatus of claim 18, wherein the gas supply unit comprises a remote plasma generator plasmatizing oxygen gas stored in the oxygen gas reservoir and supplying the plasmatized oxygen gas into the shower head.
